(19) United States
(12) Patent Application Publication
(10) Pub. No.: US 2013/0065367 A1
(43) Pub. Date: Mar. 14, 2013

(54) Methods of Forming Highly Scaled Semiconductor Devices Using a Reduced Number of Spacers

(71) Applicants: Stefan Flachowsky, Dresden (DE); Thilo Scheiper, Dresden (DE); Ricardo P. Mikalo, Heideblick (DE)

(72) Inventors: Stefan Flachowsky, Dresden (DE); Thilo Scheiper, Dresden (DE); Ricardo P. Mikalo, Heideblick (DE)

(73) Assignee: GLOBALFOUNDRIES INC., Grand Cayman (KY)

(21) Appl. No.: 13/231,470

(22) Filed: Sep. 13, 2011

(51) Int. Cl. H01L 21/8238

(52) U.S. Cl. 438/231; 257/E21.633

(57) ABSTRACT

In one example, a method disclosed herein includes the steps of forming gate electrode structures for a PMOS transistor and for an NMOS transistor, forming a first spacer proximate the gate electrode structures, after forming the first spacer, forming extension implant regions in the substrate for the transistors and after forming the extension implant regions, forming a second spacer proximate the first spacer for the PMOS transistor. This method also includes performing an etching process with the second spacer in place to define a plurality of cavities in the substrate proximate the gate structure for the PMOS transistor, removing the first and second spacers, forming a third spacer proximate the gate electrode structures of both of the transistors, and forming deep source/drain implant regions in the substrate for the transistors.

### BACKGROUND OF THE INVENTION

1. Field of the Invention

Generally, the present disclosure relates to the manufacturing of sophisticated semiconductor devices, and, more specifically, to various methods of forming highly scaled semiconductor devices using a novel process flow that involves a reduced number of spacers.

2. Description of the Related Art

The fabrication of advanced integrated circuits, such as CPU's, storage devices, ASIC's (application specific integrated circuits) and the like, requires the formation of a large number of circuit elements in a given chip area according to a specified circuit layout, wherein field effect transistors (NMOS and PMOS transistors) represent one important type of circuit elements that substantially determine performance of the integrated circuits. During the fabrication of complex integrated circuits using, for instance, MOS technology, millions of transistors, e.g., NMOS transistors and/or PMOS transistors are formed on a substrate including a crystalline semiconductor layer. A field effect transistor, irrespective of whether an NMOS transistor or a PMOS transistor is considered, typically comprises so-called PN junctions that are formed by an interface of highly doped regions, referred to as drain and source regions, with a slightly doped or non-doped region, such as a channel region, disposed between the highly doped regions source/drain regions.

In a field effect transistor, the conductivity of the channel region, i.e., the drive current capability of the conductive channel is controlled by a gate electrode formed adjacent to the channel region and separated therefrom by a thin gate insulation layer. The conductivity of the channel region, upon formation of a conductive channel due to the application of an appropriate control voltage to the gate electrode, depends upon, among other things, the dopant concentration, the mobility of the charge carriers and, for a given extension of the channel region in the transistor width direction, the distance between the source and drain regions, which is also referred to as the channel length of the transistor. Hence, in combination with the capability of rapidly creating a conductive channel below the insulating layer upon application of the control voltage to the gate electrode, the conductivity of the channel region substantially affects the performance of MOS transistors. Thus, since the speed of creating the channel, which depends in part on the conductivity of the gate electrode, and the channel resistivity substantially determine the characteristics of the transistor, the scaling of the channel length, and associated therewith the reduction of channel resistivity, are dominant design efforts used to increase the operating speed of the integrated circuits.

The formation of transistors typically involves performing one or more ion implantation processes to form various doped regions in the substrate, such as halo implant region, extension implant regions and deep source/drain implant regions. In many of the cases, one or more spacers are formed adjacent a gate electrode structure so as to control the location of the various implant regions. Typically, these spacers are made of silicon nitride to facilitate processing. More specifically, silicon nitride is often selected because it can be readily etched, and thus removed, relative to a silicon substrate and an underlying silicon dioxide liner layer which is frequently present to act as an etch stop layer when the silicon nitride spacer is removed.

FIGS. 1A-1G depict one illustrative prior art process flow for forming a semiconductor device 100 that includes an illustrative PMOS transistor 100P and an illustrative NMOS transistor 100N using an illustrative combination of silicon nitride spacers. As shown in FIG. 1A, the process begins with the formation of illustrative gate electrode structures 14 for the PMOS transistor 100P and the NMOS transistor 100N in and above regions of the substrate 10 that are separated by an illustrative shallow trench isolation structure 12. The gate electrode structures 14 generally include a gate insulation layer 14A and one or more conductive gate electrode layers 14B. A gate cap layer 16, made of a material such as silicon nitride, is formed above the gate structures 14. Also depicted in FIG. 1A is an illustrative liner layer 18, made of a material such as silicon dioxide having a thickness of approximately 3-5 nm, that is conformally deposited on the device 100. The gate electrode structures 14 depicted herein are intended to be schematic and representative in nature, as the materials of construction used in the gate structures 14 may be different for the PMOS transistor 100P as compared to the NMOS transistor 100N, e.g., the PMOS transistor 100P may have multiple layers of conductive metal, etc. The gate insulation layer 14A may be comprised of a variety of materials, such as silicon dioxide, silicon oxynitride, a high-k (k value greater than 10) insulating material. The gate electrode layer 14B may be comprised of one or more layers of conductive materials, such as polysilicon, a metal, etc. The structure depicted in Figure lA may be formed by a performing a variety of know techniques. For example, the layers of material that make up the gate insulation layer 14A, the gate electrode layer 14B and the gate cap layer 16 may be blanket-deposited above the substrate 10 and, thereafter, one or more etching process are performed through a patterned mask layer (not shown) to define the basic structures depicted in FIG. 1A. Thereafter, a conformal deposition process is performed to form the liner layer 18.

FIG. 1B depicts the device 100 after several process operations have been performed. More specifically, illustrative silicon nitride spacers 20 with an illustrative base width of about 5-10 nm are formed adjacent the liner layer 18 for both the PMOS transistor 100P and the NMOS transistor 100N. The spacers 20 may be formed by depositing a layer of spacer material and thereafter performing anisotropic etching process. Exposed horizontal portions of the oxide liner layer 18 are removed after the spacers 20 are formed. Next, a masking layer (not shown), e.g., such a photoresist mask, is formed so as to cover the NMOS transistor 100N and expose the PMOS transistor 100P for further processing. Then, one or more ion implantation processes are performed on the exposed PMOS transistor 100P to form various doped regions in the substrate 10. More specifically, at the point depicted in FIG. 1B, an angled ion implant process may be performed using an N-type dopant material to form so-called halo implant regions 21P in the substrate 10 for the PMOS transistor 100P, and another vertical ion implant process may be performed using a P-type dopant material to form extension implant regions 23P for the PMOS transistor 100P. Thereafter, a very quick anneal process, such as a laser anneal process, may be performed at a temperature of about 1250° C. for about 10 milliseconds or so to repair the damaged lattice structure of the substrate 10 in the areas that were subjected to the ion implant processes discussed above. The implant regions 21P, 23P are depicted schematically and they are located in a position where they will be after the anneal process has been performed where some migration of the implanted dopant material may have occurred.

FIG. 1C also depicts the device 100 after several process operations have been performed on the device 100. More specifically, a hard mask layer 17, made of a material such as silicon nitride, is formed above the NMOS transistor 100N and the PMOS transistor 100P. The hard mask layer 17 may be formed by blanket-depositing the hard mask layer 17 across the device 100 and, thereafter, forming a masking layer (not shown), e.g., such a photoresist mask so as to cover the NMOS transistor 100N and expose the PMOS transistor 100P for further processing. Then an anisotropic etching process is performed to remove the hard mask layer 17 from above the PMOS transistor 100P. This process results in the formation of a second spacer 22 adjacent the spacer 20 on the PMOS transistor 100P. In some embodiments, the spacer 22 may have a base width of about 4-8 nm. Next, one or more etching processes are performed to define cavities 24 in areas of substrate 10 where source/drain regions for the PMOS transistor 100P will ultimately be formed. The depth and shape of the cavities 24 may vary depending upon the particular application. In one example, where the cavities 24 have an overall depth 25 of about 70 nm, the cavities 24 may be formed by performing an initial dry anisotropic etching process to a depth of about 40-50 nm and thereafter, performing a wet etching process using, for example TMAH, which has an etch rate that varies based upon the crystalline structure of the substrate 10, e.g., the etching process using TMAH exhibits a higher etch rate in the 110 direction than it does in the 100 direction.

FIG. 1D depicts the device 100 after an epitaxial deposition process is performed to form epitaxial silicon germanium regions 26 in the cavities 24. In the depicted example, the regions 26 have an overfill portion that extends above the surface 10S of the substrate 10. In the depicted example, the uppermost surface of the epitaxial silicon germanium regions 26 extends above the substrate 10 by a distance 27 of about 25 nm. The regions 26 may be formed by performing well know epitaxial deposition processes. The device 100 in FIG. 1D has also be subjected to an etching process using, for example, hot phosphoric acid, to remove all of the exposed nitride materials, such as the hard mask layer 17, the spacers 20, the spacers 22 and the gate cap layer 16.

As shown in FIG. 1E, any remaining portions of the original liner layer 18 may be removed and new liner layer 18A comprised of, for example, 3-5 nm of silicon dioxide, may be formed it its place. Alternatively the original liner layer 18 may remain in place. Thereafter, illustrative silicon nitride spacers 28 with an illustrative base width of about 5-10 nm are formed adjacent the liner layer 18A for both the PMOS transistor 100P and the NMOS transistor 100N. The spacers 28 may be formed by depositing a layer of spacer material and thereafter performing an anisotropic etching process. Next, a masking layer (not shown), e.g., such a photoresist mask, is formed so as to cover the PMOS transistor 100P and expose the NMOS transistor 100N for further processing. Then, one or more ion implantation processes are performed on the exposed NMOS transistor 100N to form various doped regions in the substrate 10. More specifically, at the point depicted in FIG. 1E, an angled ion implant process may be performed using an P-type dopant material to form so-called halo implant regions 21N in the substrate 10 for the NMOS transistor 100N, and another vertical ion implant process may be performed using an N-type dopant material to form extension implant regions 23N for the NMOS transistor 100N. Thereafter, a very quick anneal process, such as a laser anneal process, may be performed at a temperature of about 1250° C. for about 10 milliseconds or so to repair the damaged lattice structure of the substrate 10 in the areas that were subjected to the ion implant processes discussed above. The implant regions 21N, 23N are depicted schematically and they are located in a position where they will be after the anneal process has been performed wherein some migration of the implanted dopant material may have occurred.

Next, as shown in FIG. 1F, silicon nitride spacers 30 are formed form both the PMOS transistor 100P and the NMOS transistor 100N. Although not depicted in the drawings, another conformal liner layer of, for example, 3-5 nm of silicon dioxide, may be formed so as to cover the spacers 28 prior to forming the spacers 30. Thereafter, deep source/drain ion implant processes are performed on the PMOS transistor 100P and the NMOS transistor 100N using appropriate masking layers and appropriate dopant materials, all of which are well known to those skilled in the art, to form P-doped source/drain implant regions 29P on the PMOS transistor 100P and N-doped source/drain implant regions 29N on the NMOS transistor 100N. One or more anneal processes are then performed to repair lattice damage to the substrate and to activate the implanted dopant material.

FIG. 1G depicts the device 100 after metal silicide regions 32 have been formed on the device 100. More specifically, the metal silicide regions 32 are formed on the gate electrode 14B and on the source/drain regions of the transistors 100P, 100N. So as not to obscure the drawings, the various doped regions described previously are not depicted in FIG. 1G. The metal silicide regions 32 may be made of any metal silicide and they may be formed using traditional silicidation techniques. The metal silicide regions 32 need not be the same metal silicide material on both the PMOS transistor 100P and the NMOS transistor 100N, although that may be the case. Although not depicted in the drawings, the fabrication of the device 100 would include several additional steps such as the formation of a plurality of conductive contacts or plugs in a layer of insulating material so as to establish electrical connection with the source/drain regions of the transistors.

The above disclosed technique provides for the formation of four spacers as various points in the process flow. The formation of so many spacers during the above-described process flow provides a mechanism whereby the location of various doped regions may be positioned so as to individually enhance the performance capabilities of the PMOS transistor 100P and the NMOS transistor 100N, the formation of so many spacers does have a downside. More specifically, during the formation of the various spacers, the exposed substrate, i.e., the areas of the substrate where the source/drain regions are to be formed, are also attacked which leads to undesirable localized recessing of the substrate in those areas. In some application, such recessing may remove about 5-8 nm of the substrate 10. Such recessing may, in effect, consume some of the implanted dopant materials in the substrate 10.

Such recessing may result in increased parasitic resistance which may reduce the drive current of the device 100. Such recessing may also effectively increase the distance current must travel through the device 100, which may tend to reduce the operating speed of the device 100.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming highly scaled semiconductor devices using a novel process flow that involves a reduced number of spacers. In one example, a method disclosed herein includes the steps of forming gate electrode structures for a PMOS transistor and for an NMOS transistor above a semiconducting substrate, forming a first spacer proximate the gate electrode structures of both the PMOS transistor and the NMOS transistor, after forming the first spacer, performing a plurality of extension ion implant processes to form extension implant regions in the substrate for the PMOS transistor and the NMOS transistor and after forming the extension implant regions, forming a second spacer proximate the first spacer for said PMOS transistor. This illustrative method includes the further steps of performing at least one etching process with said second spacer in place to define a plurality of cavities in the substrate proximate the gate structure for the PMOS transistor, removing the first and second spacers, after removing the first and second spacers, forming a third spacer proximate the gate electrode structures of both the PMOS transistor and the NMOS transistor, and performing a plurality of source/drain ion implant processes to form deep source/drain implant regions in the substrate for the PMOS transistor and the NMOS transistor.

In another illustrative example, a method disclosed herein includes forming gate electrode structures for a PMOS transistor and for an NMOS transistor above a semiconducting substrate and forming extension implant regions in the substrate for both the PMOS transistor and the NMOS transistor. This illustrative method also includes the steps of, after forming the extension implant regions, performing at least one etching process to define a plurality of cavities in the substrate proximate the gate structure for the PMOS transistor and after forming the cavities, forming deep source/drain implant regions in the substrate for the PMOS transistor and the NMOS transistor.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1G depict one illustrative prior art process flow for forming a semiconductor device; and

FIGS. 2A-2F depict various illustrative examples of using the methods disclosed herein to form forming highly scaled semiconductor devices using a novel process flow that involves a reduced number of spacers.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

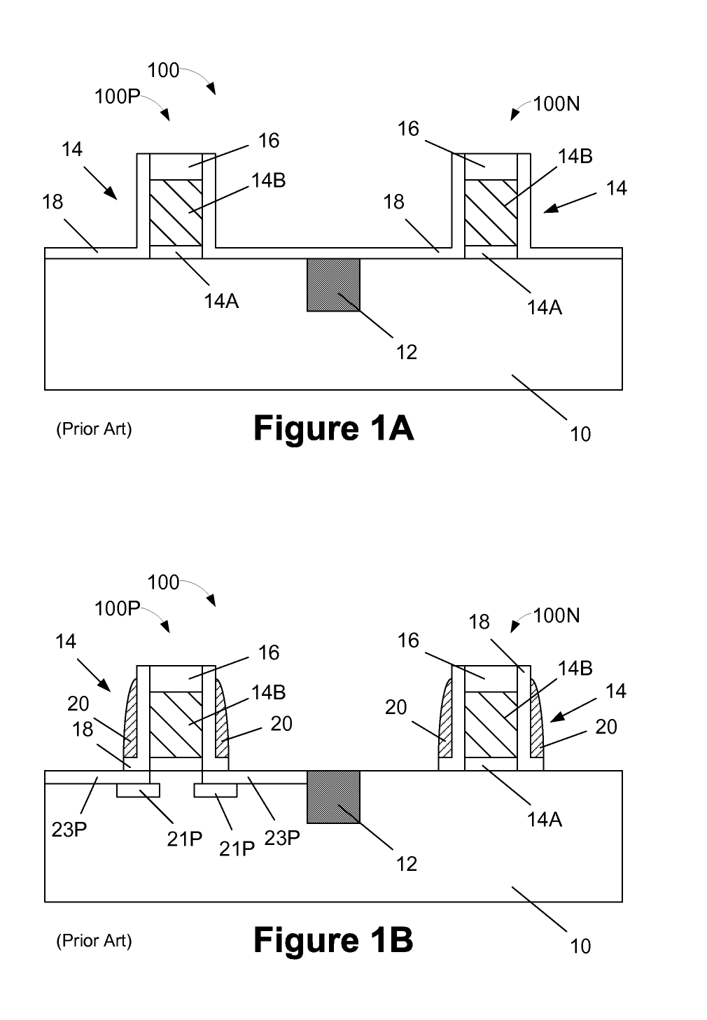

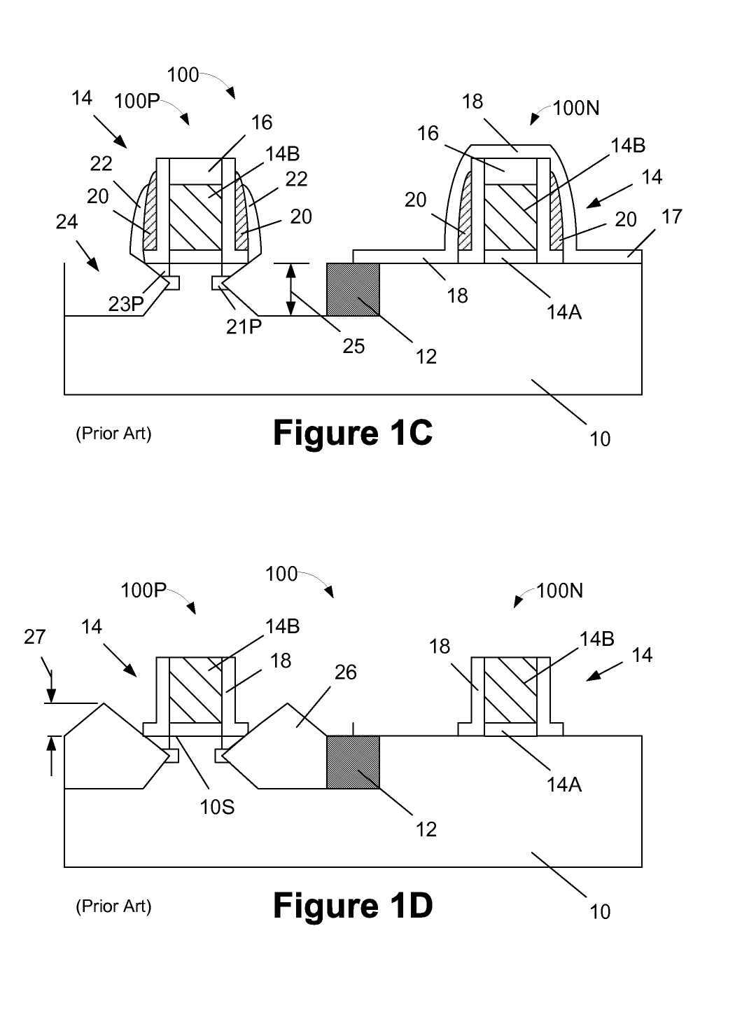

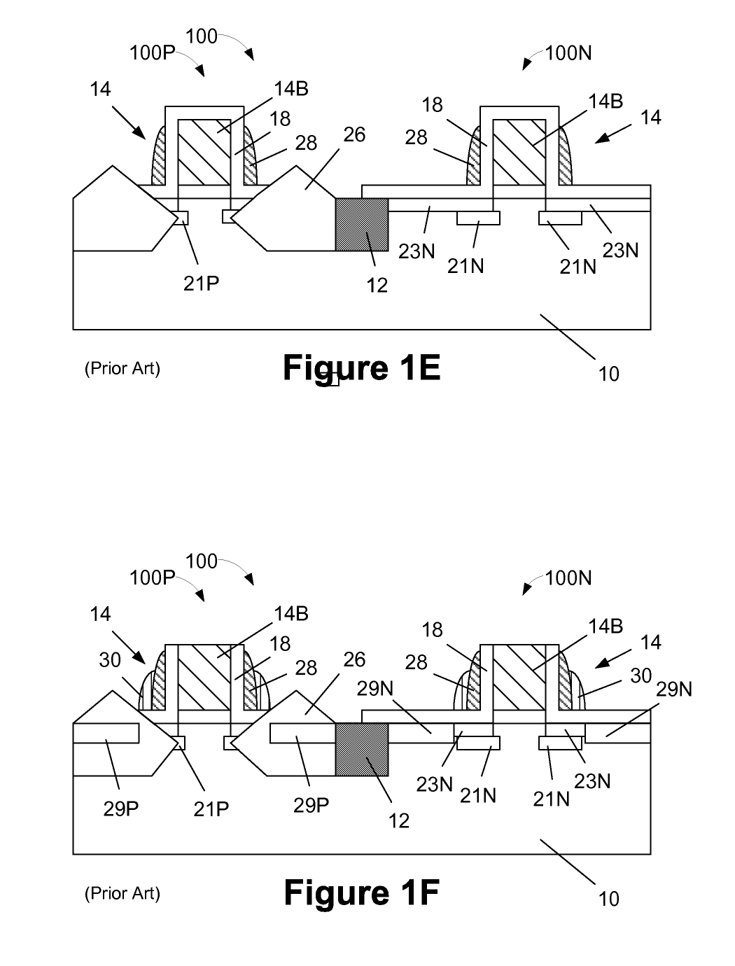

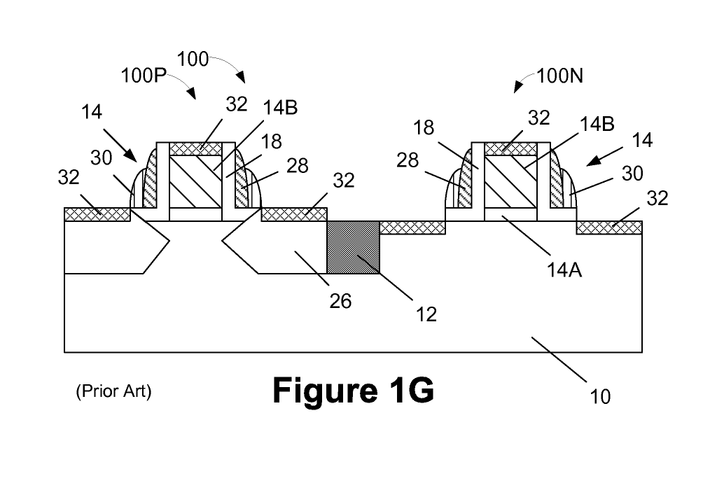

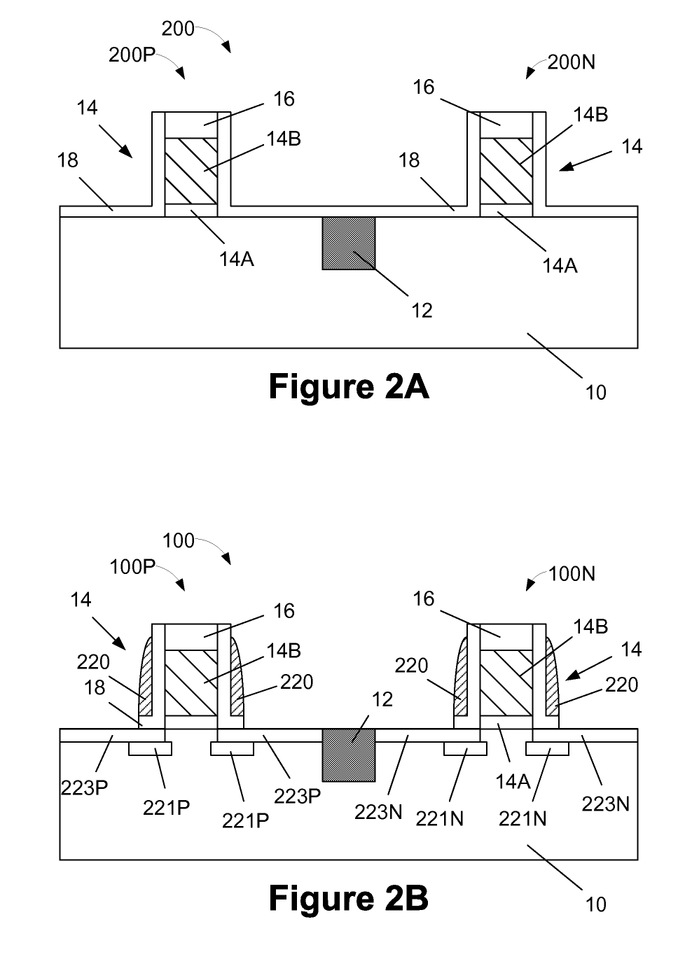

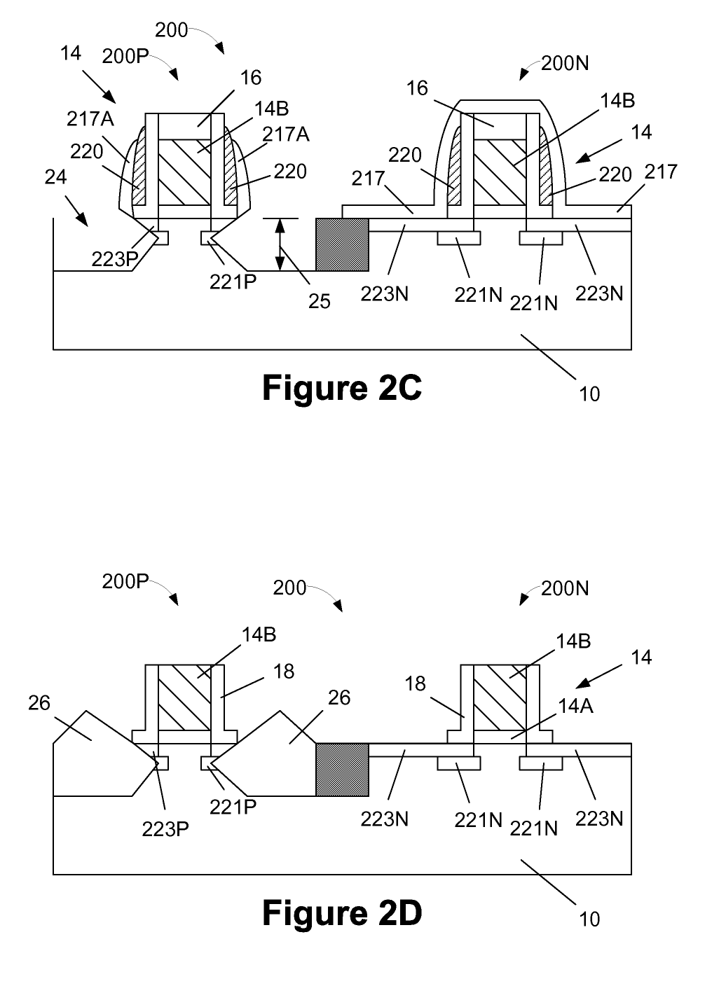

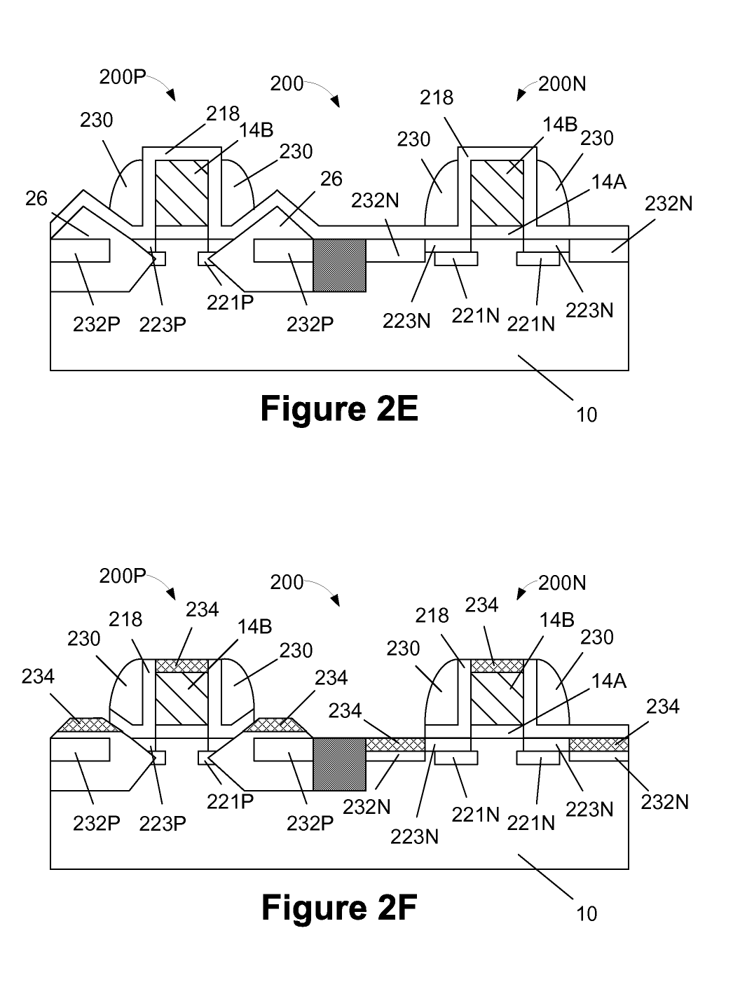

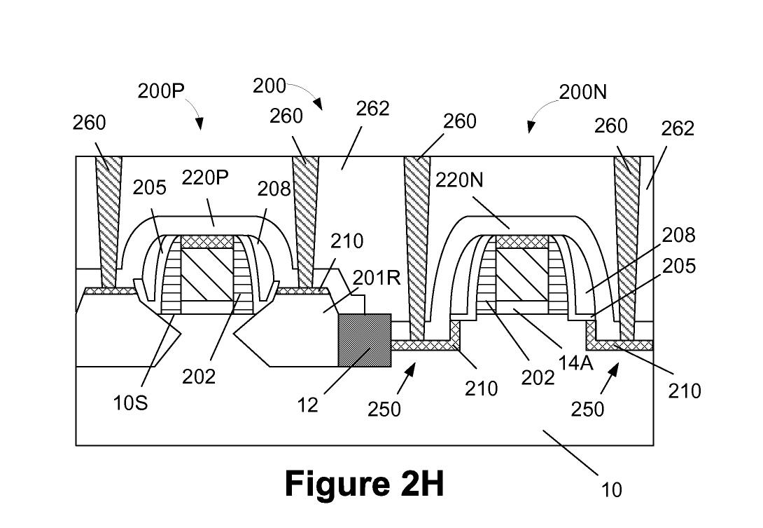

The present disclosure is directed to various methods of forming highly scaled semiconductor devices using a novel process flow that involves a reduced number of spacers as compared to the prior art process flow described above in connection with FIGS. 1A-1G. Such a novel process flow may tend to reduce the undesirable recessing of the substrate, as discussed in the background section of this application. Moreover, such a novel process flow may tend to at least reduce some of the problems associated with the illustrative prior art process flow described previously. As will be readily apparent to those skilled in the art upon a complete reading of the present application, the present method is applicable to a variety of technologies, e.g., MOS-based technologies, etc., and is readily applicable to a variety of devices, including, but not limited to, logic devices, memory devices, etc. With reference to FIGS. 2A-2F, various illustrative embodiments of the methods and devices disclosed herein will now be described in more detail. To the extent that like numbers of various components is used in FIGS. 2A-2F and FIGS. 1A-1G, the previous discussion of those components in connection with the device 100 applies equally as well to the device 200.

FIG. 2A is a simplified view of an illustrative semiconductor device 200 at an early stage of manufacture. The semiconductor device 200 includes an illustrative PMOS transistor 200P and an illustrative NMOS transistor 200N. As shown in FIG. 2A, the process begins with the formation of illustrative gate structures 14 for the PMOS transistor 200P and the NMOS transistor 200N in and above regions of the substrate 10 that are separated by an illustrative shallow trench isolation structure 12. Also depicted in FIG. 2A is an illustrative cap layer 16 and an illustrative liner layer 18, made of a material such as silicon dioxide having a thickness of approximately 3-5 nm. The substrate 10 may have a variety of configurations, such as the depicted bulk silicon configuration. The substrate 10 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all forms of semiconductor structures. The substrate 10 may also be made of materials other than silicon. As will be recognized by those skilled in the art after a complete reading of the present application, the gate structures 14 may be of any desired construction and comprised of any of a variety of different materials, such as one or more conductive layers made of polysilicon or a metal, etc., and one or more layers of insulating material, such as silicon dioxide, a high-k material, etc. Additionally, the gate structure 14 for the NMOS transistor 200N may have different material combinations as compared to a gate structure 14 for the PMOS transistor 200P. Thus, the particular details of construction of gate structure 14, and the manner in which the gate structures 14 are formed, should not be considered a limitation of the present invention. For example, the gate structures 14 may be made using so-called “gate-first” or “gate-last” techniques.

FIG. 2B depicts the device 200 after several process operations have been performed. More specifically, an illustrative first spacer 220 with an illustrative base width of about 5-10 nm are formed adjacent gate structures for both the PMOS transistor 200P and the NMOS transistor 200N. The first spacer 220 may be comprised of a variety of different materials and it may be formed by depositing a layer of spacer material and thereafter performing anisotropic etching process. Exposed horizontal portions of the oxide liner layer 18 may be removed after the first spacer 220 is formed.

Next, using appropriate masking layers, various implantation processes are performed to form halo implant regions and extension implant regions in both the PMOS transistor 200P and the NMOS transistor 200N. The implant regions may be formed in any order, i.e., the implant regions may be formed first on either of the PMOS transistor 200P or the NMOS transistor 200N. In one illustrative process flow, a masking layer (not shown), e.g., such a photoresist mask, is formed so as to cover the NMOS transistor 200N and expose the PMOS transistor 200P such that various doped regions for the PMOS transistor 200P may be formed in the substrate 10. More specifically, at the point depicted in FIG. 2B, an angled halo ion implant process has been performed using an N-type dopant material to form the schematically depicted halo implant regions 221P for the PMOS transistor 200P, and another vertical extension ion implant process has been performed using a P-type dopant material to form extension implant regions 223P for the PMOS transistor 200P.

Next, the masking layer above the NMOS transistor 200N is removed and a masking layer (not shown), e.g., such a photoresist mask, is formed so as to cover the PMOS transistor 200P and expose the NMOS transistor 200N such that various doped regions for the NMOS transistor 200N may be formed in the substrate 10. More specifically, at the point depicted in FIG. 2B, an angled halo ion implant process has been performed using a P-type dopant material to form the schematically depicted halo implant regions 221N for the NMOS transistor 200N, and another vertical extension ion implant process has been performed using an N-type dopant material to form extension implant regions 223N for the NMOS transistor 200N.

Thereafter, in one illustrative embodiment, a very quick anneal process, such as a laser anneal process, may be performed at a temperature of about 1250° C. for about 10 milliseconds or so to repair the damaged lattice structure of the substrate 10 in the areas that were subjected to the ion implant processes discussed above. The implant regions 221P, 223P, 221N, 223N are depicted schematically and they are located in a position where they will be after the anneal process has been performed where some migration of the implanted dopant material may have occurred.

FIG. 2C also depicts the device 200 after several process operations have been performed on the device 200. More specifically, a hard mask layer 217, made of a material such as silicon nitride, is formed above the NMOS transistor 200N and the PMOS transistor 200P. The hard mask layer 217 may be formed by blanket-depositing the hard mask layer 217 across the device 200 and, thereafter, forming a masking layer (not shown), e.g., such a photoresist mask so as to cover the NMOS transistor 200N and expose the PMOS transistor 200P for further processing. Then an anisotropic etching process is performed to remove the hard mask layer 217 from above the PMOS transistor 200P. This process results in the formation of a second spacer 217A adjacent the spacer 220 on the PMOS transistor 200P. In some embodiments, the second spacer 217A may have a base width of about 4-8 nm. Next, one or more etching processes are performed to define cavities 24 in areas of substrate 10 where source/drain regions for the PMOS transistor 200P will ultimately be formed. The depth and shape of the cavities 24 may vary depending upon the particular application as noted previously in connection with the discussion of the prior art device 100.

FIG. 2D depicts the device 200 after several process operations have been performed. First, an epitaxial deposition process is performed to form epitaxial silicon germanium or silicon carbon material regions 26 in the cavities 24. In the depicted example, the regions 26 have an overfill portion that extends above the surface 10S of the substrate 10. The epitaxial silicon germanium regions 26 may be formed by performing well know epitaxial deposition processes. Then, the device 200 is subjected to an etching process using, for example, hot phosphoric acid, to remove all of the exposed nitride materials, such as the hard mask layer 217, the spacers 220, the spacers 217A and the gate cap layer 16.

As shown in FIG. 2E, any remaining portions of the original liner layer 18 may be removed and new liner layer 218 comprised of, for example, 3-5 nm of silicon dioxide, may be formed it its place by performing a conformal deposition process. Alternatively the original liner layer 18 may remain in place. Thereafter, a relatively large, third spacer 230, with an illustrative base width of about 20-25 nm, is formed proximate the gate structures for both the PMOS transistor 200P and the NMOS transistor 200N. The third spacers 230 may comprised of a variety of materials, such as silicon nitride, and they may be formed by depositing a layer of spacer material and thereafter performing an anisotropic etching process.

Next, using appropriate masking layers, various deep source/drain ion implantation processes are performed to form deep source/drain implant regions in both the PMOS transistor 200P and the NMOS transistor 200N. The deep source/drain implant regions may be formed first on either of the PMOS transistor 200P or the NMOS transistor 200N. In one illustrative process flow, a masking layer (not shown), e.g., such a photoresist mask, is formed so as to cover the PMOS transistor 200P and expose the NMOS transistor 200N for further processing. Then, an ion implantation process is performed to form P-doped deep source/drain implant regions 232P for the PMOS transistor 200P. Next, the masking layer above the NMOS transistor 200N is removed and a masking layer (not shown), e.g., such a photoresist mask, is formed so as to cover the PMOS transistor 200P and expose the NMOS transistor 200N such that the source/drain doped regions for the NMOS transistor 200N may be formed in the substrate 10. More specifically, another vertical ion implant process is performed using an N-type dopant material to form deep source/drain implant regions 232N for the NMOS transistor 200N.

Thereafter, in one illustrative embodiment, a very quick anneal process, such as a laser anneal process, may be performed at a temperature of about 1250° C. for about 10 milliseconds or so to repair the damaged lattice structure of the substrate 10 in the areas that were subjected to the ion implant processes discussed above and to activate the implanted dopant materials. The implant regions 232P, 232N are depicted schematically and they are located in a position where they will be after the anneal process has been performed wherein some migration of the implanted dopant material may have occurred.

FIG. 2F depicts the device 200 after several process operations have been performed. Initially, an etching process is performed to remove the exposed portions of the liner layer 218. This exposes the illustrative polysilicon gate electrode 14B and the source/drain areas of the substrate 10 such that metal silicide regions 234 may be formed in those areas. The metal silicide regions 234 may be made of any metal silicide and they may be formed using traditional silicidation techniques. The typical steps performed to form metal silicide regions are: (1) depositing a layer of refractory metal; (2) performing an initial heating process causing the refractory metal to react with underlying silicon containing material; (3) performing an etching process to remove unreacted portions of the layer of refractory metal and (4) performing an additional heating process to form the final phase of the metal silicide. The details of such silicidation processes are well known to those skilled in the art. The metal silicide regions 234 need not be the same metal silicide material on both the PMOS transistor 200P and the NMOS transistor 200N, although that may be the case. Although not depicted in the drawings, the fabrication of the device 200 would include several additional steps such as the formation of a plurality of conductive contacts or plugs in a layer of insulating material so as to establish electrical connection with the source/drain regions of the transistors.

It should be noted that, when it is stated in this detailed description or in the claims, that certain spacers or combinations of spacers are positioned “proximate” to a structure or component, such as a gate structure, such language will be understood to cover situations where such a spacer or combinations of spacers actually contacts the structure or component, as well as a situation where there are one or more intervening layers of material between the spacer and the structure or component. For example, in some cases, there may be a liner layer or other spacers positioned between the referenced spacer and referenced structure, such as the illustrative gate structures 14 depicted herein. Additionally, the fact that the claims may make shorthand reference to a “first” spacer or a “first” type of process, such language does not mean that such a spacer or process was literally the first such spacer or process that was made or performed on the device 200.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming gate electrode structures for a PMOS transistor and for an NMOS transistor above a semiconducting substrate;
forming a first spacer proximate said gate electrode structures of both said PMOS transistor and said NMOS transistor;
after forming said first spacer, performing a plurality of extension ion implant processes to form extension implant regions in said substrate for said PMOS transistor and said NMOS transistor;
after forming said extension implant regions, forming a second spacer proximate said first spacer for said PMOS transistor;
performing at least one etching process with said second spacer in place to define a plurality of cavities in said substrate proximate said gate structure for said PMOS transistor;
removing said first and second spacers;
after removing said first and second spacers, forming a third spacer proximate said gate electrode structures of both said PMOS transistor and said NMOS transistor; and
performing a plurality of source/drain ion implant processes to form deep source/drain implant regions in said substrate for said PMOS transistor and said NMOS transistor.

2. The method of claim 1, further comprising performing at least one heating process to activate dopants implanted during said extension ion implant processes and to activate dopants implanted during said source/drain ion implant processes.

3. The method of claim 1, further comprising, prior to forming said first spacer, forming a liner layer on said gate structures of said PMOS transistor and said NMOS transistor, wherein said first spacer is formed said liner layer.

4. The method of claim 1, wherein said first, second and third spacers are each comprised of silicon nitride.

5. The method of claim 1, further comprising, prior to forming said second spacer, performing a plurality of halo ion implant processes to form halo implant regions in said substrate for said PMOS transistor and said NMOS transistor.

6. The method of claim 5, wherein for each of said PMOS transistor and said NMOS transistor, said halo ion implant process is performed prior to performing said extension ion implant process.

7. The method of claim 5, wherein for each of said PMOS transistor and said NMOS transistor, said halo ion implant process is performed after performing said extension ion implant process.

8. The method of claim 1, further comprising performing an epitaxial deposition process to form a silicon germanium material or a silicon carbon material in said cavities.

9. The method of claim 1, wherein said first spacer has a base width of about 5-10 nm, said second spacer has a base width of about 4-8 nm and said third spacer has a base width of about 20-25 nm.

10. A method, comprising:
forming gate electrode structures for a PMOS transistor and for an NMOS transistor above a semiconducting substrate;
forming extension implant regions in said substrate for both said PMOS transistor and said NMOS transistor;
after forming said extension implant regions, performing at least one etching process to define a plurality of cavities in said substrate proximate said gate structure for said PMOS transistor; and
after forming said cavities, forming deep source/drain implant regions in said substrate for said PMOS transistor and said NMOS transistor.

11. The method of claim 10 further comprising, prior to forming said cavities, performing a plurality of halo implant regions in said substrate for said PMOS transistor and said NMOS.

12. The method of claim 11, wherein for each of said PMOS transistor and said NMOS transistor, said halo implant regions are formed prior to said extension implant regions.

13. The method of claim 11, wherein for each of said PMOS transistor and said NMOS transistor, said halo implant regions are formed after said extension implant regions.

14. The method of claim 10, further comprising performing an epitaxial deposition process to form a silicon germanium material or a silicon carbon material in said cavities.
